(19) United States
(12) Patent Application Publication
(10) Pub. No.: US 2024/0130200 A1
(43) Pub. Date: Apr. 18, 2024

(54) DISPLAY DEVICE

(71) Applicant: LG Display Co., Ltd., Seoul (KR)

(72) Inventor: Min-Ji KANG, Paju-si (KR)

(73) Assignee: LG Display Co., Ltd., Seoul (KR)

(21) Appl. No.: 18/478,409

(22) Filed: Sep. 29, 2023

(30) Foreign Application Priority Data
Oct. 18, 2022 (KR) 10-2022-0134011

(51) Int. Cl. H10K 59/80; H10K 59/122

(52) U.S. Cl. CPC H10K 59/873; H10K 59/122

(57) ABSTRACT

A display device in one example includes a substrate having a display area displaying an image and a non-display area adjacent to the display area, and a thin film transistor disposed on the substrate and including a semiconductor layer, a gate electrode, a source electrode and a drain electrode. The display device further includes an emitting element disposed on the thin film transistor in the display area and including a first electrode, an emitting layer and a second electrode, an encapsulating part disposed on the emitting element, a first line disposed in the non-display area and including a same metallic material as the first electrode and connected to the second electrode, and a plurality of first dams disposed on the first line. The first line includes a plurality of open parts, and the plurality of first dams are disposed on the plurality of open parts.

### CROSS REFERENCE TO RELATED APPLICATIONS

The present application claims priority to Korean Patent Application No. 10-2022-0134011 filed in Republic of Korea on Oct. 18, 2022, the entire disclosure of which is hereby expressly incorporated by reference into the present application.

### BACKGROUND

### Technical Field

The present disclosure relates to a display device, and more particularly, to a display device where a non-display area (e.g., size thereof) is reduced by disposing a dam on a line in the non-display area.

### Discussion of the Related Art

A display device for displaying an image in a television, a monitor, a smart phone, a tablet PC, a notebook PC and the like can be of various types and can have various shapes.

Among such display devices of various types, a liquid crystal display (LCD) device has been used, and an application range of an organic light emitting diode (OLED) display device has been rapidly enlarged.

The display device includes a display panel having a thin film transistor (TFT) for individually controlling an emitting element or a liquid crystal and the operation of the emitting element or the liquid crystal.

Since an LCD device is not of an emissive type, a light source such as a backlight unit for supplying a light at a rear is needed. Due to the backlight unit, however, the thickness of the LCD device can increase, which can be an issue in providing a display device which is flexible or has a design of various shapes.

An OLED display device having an emitting element does not require an additional light source and has a thickness smaller than a device having a light source. As a result, a display device which is flexible or has a design of various shapes can be obtained using the emitting elements.

A thin film transistor is disposed in the OLED display device for driving the emitting element, and the OLED display device is driven by applying a voltage to the emitting element.

However, when a moisture or an external particle penetrates into the emitting element of the OLED display device, the emitting element can deteriorate and may not operate properly.

As a result, an encapsulating part for preventing penetration of a moisture or an external particle into the emitting element can be further disposed, and a plurality of dams can be disposed to prevent the encapsulating part from being formed at a periphery of a display panel.

Since a non-display area for forming the plurality of dams is enlarged and a total size of the OLED display device can thus be enlarged, portability of the OLED display device can be reduced and the OLED display device can have a drawback in a design.

### SUMMARY OF THE DISCLOSURE

Accordingly, embodiments of the present disclosure are directed to a display device that substantially obviates one or more of problems due to the limitations and disadvantages of the related art.

An object of the present disclosure is to provide a display device where a non-display area is reduced (e.g., size thereof) by disposing a portion of the plurality of dams on a first line where a driving voltage (e.g., a common voltage, a driving signal, etc.) is applied.

Another object of the present disclosure is to provide a display device where a contact resistance of a first line and a first electrode of an emitting element is reduced by exposing a portion of the first line between a plurality of dams and connecting the exposed first line and a first electrode.

Another object of the present disclosure is to provide a display device where a reliability is improved due to a first line including an open part for expelling residual gas in a display panel and a mesh part of a net shape.

Another object of the present disclosure is to provide a display device where a residue of a first line is prevented by overlapping a plurality of dams and an end portion of a mesh part.

Additional features and advantages of the disclosure will be set forth in the description which follows, and in part will be apparent to those skilled in the art from the description or can be learned by practice of the disclosure. These and other advantages of the disclosure can be realized and attained by the structure particularly pointed out in, or derivable from, the written description, claims hereof, and the appended drawings.

Embodiments described herein relate to display devices that achieve the above-described advantages. In one embodiment, a display device includes: a substrate having a display area for displaying an image and a non-display area surrounding the display area; a thin film transistor disposed on the substrate and including a semiconductor layer, a gate electrode, a source electrode and a drain electrode; an emitting element disposed on the thin film transistor in the display area and including a first electrode, an emitting layer and a second electrode; an encapsulating part disposed on the emitting element; a first line disposed in the non-display area, the first line including a same metallic material as the first electrode and connected to the second electrode; and a plurality of first dams disposed on the first line, wherein the first line includes a plurality of open parts, and the plurality of first dams are disposed on the plurality of open parts.

It is to be understood that both the foregoing general description and the following detailed description are explanatory and by way of examples and are intended to provide further explanation of the disclosure as claimed without limiting its scope.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1A is a plan view showing a front surface of a display device according to an embodiment of the present disclosure;

FIG. 1B is a plan view showing a rear surface of a display device according to an embodiment of the present disclosure;

FIG. 2 is a view taken along line A-A′ of FIG. 1A;

FIG. 3 is a plan view corresponding to line B-B′ of FIG. 2;

FIG. 4A is a plan view showing a first line of a display device according to an embodiment of the present disclosure; and

FIG. 4B is a plan view showing a first dam of a display device according to an embodiment of the present disclosure.

### DETAILED DESCRIPTION OF THE EMBODIMENTS

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration can unnecessarily obscure a feature or aspect of the present disclosure, a detailed description of such known function or configuration can be omitted or a brief description can be provided.

Where the terms such as “comprise,” “have,” “include,” and the like are used, one or more other elements can be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third layer or element can be interposed therebetween.

Although the terms “first,” “second,” A, B, (a), (b), and the like can be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” can include all combinations of two or more of the first, second and third elements as well as the first, second or third element.

The term “display device” can include a display device in a narrow sense such as liquid crystal module (LCM), an organic light emitting diode (OLED) module and a quantum dot (QD) module including a display panel and a driving unit for driving the display panel. In addition, the term “display device” can include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure can include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit can be expressed as “a display device”, and an electronic apparatus of a complete product including the LCM, the OLED module and the QD module can be expressed as “a set device.” For example, a display device in a narrow sense can include a display panel of a liquid crystal, an organic light emitting diode and a quantum dot and a source printed circuit board (PCB) of a control unit for driving the display panel, and a set device can further include a set PCB of a set control unit electrically connected to the source PCB for controlling the entire set device.

The display panel of the present disclosure can include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel can include a plurality of gate lines, a plurality of data lines and a subpixel in a crossing region of the plurality of gate lines and the plurality of data lines. The display panel can include an array having a thin film transistor of an element for selectively applying a voltage to each subpixel, an emitting element layer on the array and an encapsulating substrate or an encapsulating part covering the emitting element layer. The encapsulating part can protect the thin film transistor and the emitting element layer from an external impact and can prevent or at least reduce penetration of a moisture or an oxygen into the emitting element layer. In addition, a layer on the array can include an inorganic light emitting layer, for example, a nano-sized material layer or a quantum dot.

Features of various embodiments of the present disclosure can be partially or entirely coupled to or combined with each other. They can be linked and operated technically in various ways as those skilled in the art can sufficiently understand. The embodiments can be carried out independently of or in association with each other in various combinations.

Hereinafter, a display device according to various example embodiments of the present disclosure will be described in detail with reference to the accompanying drawings. All the components of each display device according to all embodiments of the present disclosure are operatively coupled and configured.

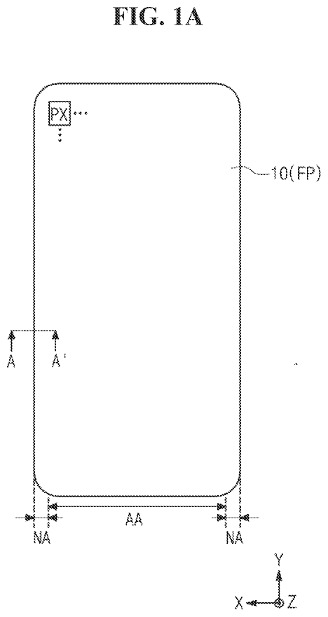

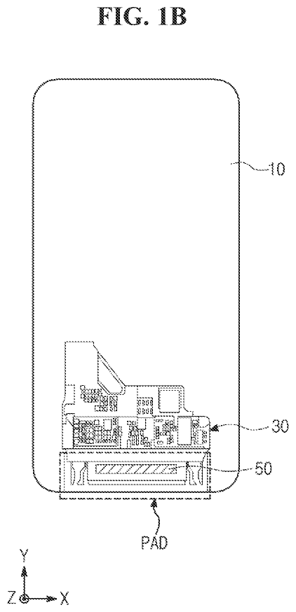

FIG. 1A is a plan view showing a front surface of a display device according to an embodiment of the present disclosure, and FIG. 1B is a plan view showing a rear surface of the display device according to an embodiment of the present disclosure.

In FIGS. 1A and 1B, the display device can include a display panel 10, a gate driving unit, a data driving unit 50 and a circuit board 30. The gate driving unit, the data driving unit 50 and the circuit board 30 can be connected to the display panel 10 to apply a driving signal and a driving voltage to the display panel 10.

The display panel 10 can include a display area (active area) AA where an image is displayed and a non-display area (non-active area) NA where the gate driving unit and the data driving unit 50 are disposed. As an example, at least one of the gate driving unit and the data driving unit 50 can be disposed in the non-display area NA in a gate-in-panel (GIP) type. As an example, at least one of the gate driving unit and the data driving unit 50 can be separately disposed and connected to the non-display area NA, for example, by a tape automated bonding (TAB) method, a chip-on-glass (COG) method, a chip on film (COF) method, etc. The display area AA can include an emitting element.

The display area AA can include a plurality of subpixels PX on a substrate for displaying an image. Each of the plurality of subpixels PX can be an individual unit emitting a light, and an emitting element and a thin film transistor can be disposed in each of the plurality of subpixels PX.

The plurality of subpixels PX can include a red subpixel, a green subpixel, a blue subpixel and/or a white subpixel. It is not limited thereto.

The non-display area NA can be a region where an image is not displayed. Various lines and a driving integrated circuit (IC) for driving the plurality of subpixels PX in the display area AA can be disposed in the non-display area NA. For example, the gate driving unit, the data driving unit 50 and the circuit board 30 can be disposed in the non-display area NA.

The non-display area NA can surround the display area AA, e.g., completely or in part. For example, the non-display area NA can extend from the display area AA, and the plurality of subpixels PX may not be disposed in the non-display area NA. The non-display area NA where an image is not displayed can be a bezel region.

The plurality of subpixels PX of the display area AA can include a thin film transistor. The thin film transistor in the display area AA can include a polycrystalline semiconductor material and/or an oxide semiconductor material. As an example, the thin film transistor in the display area AA can include other semiconductor materials such as a compound semiconductor material or an organic semiconductor material.

The gate driving unit can be formed by mounting a gate driving chip directly on the substrate, or the gate driving unit can have a gate-in-panel (GIP) type where a gate driving circuit is formed directly on the substrate. In the GIP type, a thin film transistor using a polycrystalline semiconductor material as a semiconductor layer and a thin film transistor using an oxide semiconductor material as a semiconductor layer constituting a complementary metal oxide semiconductor (CMOS) can be formed directly on the substrate. As a result, since an electron mobility increases in a channel of the thin film transistor, a display device having a relatively high resolution and a relatively low power consumption can be obtained.

A plurality of data lines and a plurality of gate lines can be disposed in the display area AA. For example, the plurality of data lines can be disposed in a row or a column, and the plurality of gate lines can be disposed in a column or a row. The plurality of subpixels PX can be disposed in a region where the plurality of data lines and the plurality of gate lines are disposed.

The display panel 10 can include a plurality of scan lines and a plurality of emission lines. The plurality of scan lines and the plurality of emission lines can transmit different gate signals (a scan signal, an emission signal) to gate electrodes of different thin film transistors (a switching transistor, a driving transistor).

The gate driving unit can include a scan driving circuit outputting the scan signal to the plurality of scan lines of a kind of a gate line and an emission driving circuit outputting the emission signal to the plurality of emission lines of another kind of a gate line.

The display panel 10 can include a front part FP, a bending part extending from the front part FP and bendable and a pad part PAD extending from the bending part and corresponding to a lower portion of the front part FP. As an example, the bending part can be omitted and the pad part PAD can be disposed in the non-display area.

The data driving unit 50 can be disposed in the pad part PAD corresponding to the lower portion of the display panel 10. The data driving unit 50 receives a digital video data and a source control signal from a timing controlling unit. The data driving unit 50 converts the digital video data into an analog data voltage according to the source control signal and supplies the analog data voltage to the plurality of data lines. The data driving unit 50 can be formed as a data driving chip and can be connected to the display panel 10 through a chip on panel (COP) type where the data driving chip is mounted directly on the pad part PAD of the display panel 10 or a chip on film (COF) type where the data driving chip is mounted on the circuit board 30.

The gate driving unit disposed in the non-display area NA sequentially supplies the scan signal to the plurality of gate lines to sequentially drive rows of subpixels PX in the display area AA. As an example, the gate driving unit can also be disposed in the pad part PAD corresponding to the lower portion of the display panel 10, and can be connected to the display panel 10 through a chip on panel (COP) type or a chip on film (COF) type.

When the selected gate line is open by the gate driving unit, the data driving unit 50 converts the image data into the data voltage of an analog type and supplies the data voltage to the plurality of data lines.

The data line can supply a common voltage and a driving voltage of the data driving unit 50 to the plurality of subpixels PX of the display area AA and can be disposed to pass through the bending part.

An end portion of the pad part PAD can be connected to the circuit board 30 having the data driving unit 50 and the timing controlling unit. The circuit board 30 can be connected to the display panel 10 through a film on panel (FOP) type. The circuit board 30 can be attached to the pad part PAD using an anisotropic conductive film (ACF) to be electrically connected to the pad part PAD.

The timing controlling unit receives the digital video data and a timing signal from an external system board. The timing controlling unit generates a gate control signal for controlling an operation timing of the gate driving unit and a data control signal for controlling the data driving unit based on the timing signal. The timing controlling unit can supply the gate control signal to the gate driving unit and can supply the data control signal to the data driving unit 50.

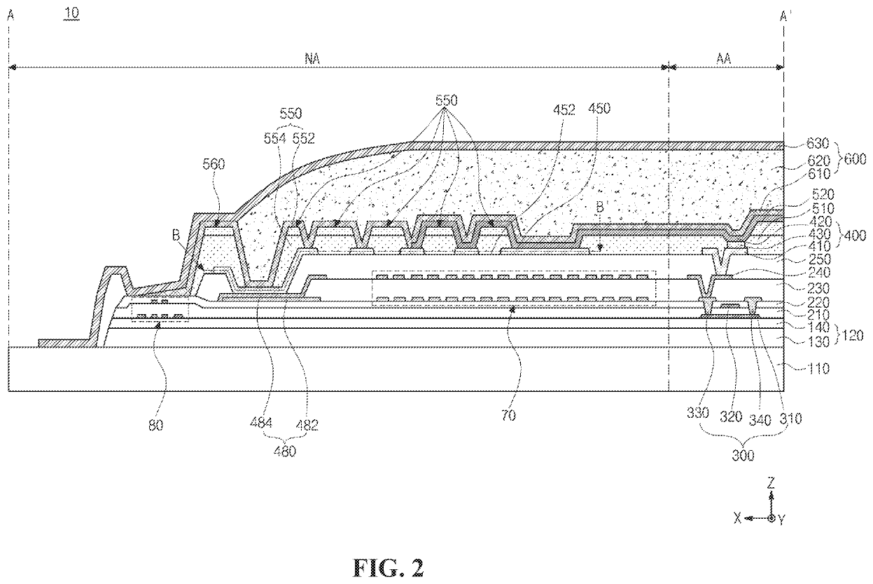

FIG. 2 is a view taken along line A-A′ of FIG. 1A. Although FIG. 2 shows a left portion of the display panel 10 in a plan view, the structure of FIG. 2 can be applied to an upper portion, a lower portion and/or a right portion of the display panel 10 in a plan view.

In FIG. 2, the substrate 110 of the display panel 10 can include a glass or a plastic material. When the substrate 110 includes a plastic material, the display panel 10 can have flexibility. As an example, the display panel 10 can be also a rigid display panel.

Similarly to the display panel 10, the substrate 110 can include a display area (active area) AA where an image is displayed and a non-display area (non-active area) NA adjacent to or surrounding the display area AA.

When the substrate 110 includes a plastic material, the substrate 110 can have a multiple layer where an organic layer and an inorganic layer are alternately laminated. For example, the substrate 110 can be formed by alternately laminating an organic layer such as polyimide and an inorganic layer such as silicon oxide. The embodiments of the present disclosure are not limited thereto.

A buffer layer 120 can be disposed on the substrate 110. The buffer layer 120 can include a lower buffer layer 130 and an upper buffer layer 140.

The lower buffer layer 130 for blocking a moisture that may be penetrating the substrate 110 from an exterior can have a single layer or a multiple layer of silicon oxide (SiO2) or silicon nitride (SiNx). The embodiments of the present disclosure are not limited thereto.

The upper buffer layer 140 protects a semiconductor layer 310 of a thin film transistor 300 and provides a base for the semiconductor layer 310. The upper buffer layer 140 can block various particles injected from the substrate 110. The upper buffer layer 140 can include amorphous silicon (a-Si).

A semiconductor layer 310 of a thin film transistor (TFT) 300 can be disposed on the buffer layer 120. The TFT 300 can include the semiconductor layer 310, a gate electrode 320, a source electrode 330 and a drain electrode 340 and can provide a driving current to an emitting element 400 according to a data voltage applied from a data line. The semiconductor layer 310 of the TFT 300 can include an oxide semiconductor material or a polycrystalline semiconductor material.

A gate insulating layer 210 and a gate electrode 320 can be sequentially disposed on the semiconductor layer 310. For example, the gate insulating layer 210 can include an inorganic material such as silicon nitride (SiNx), silicon oxynitride (SiON), silicon oxide (SiOx), titanium oxide (TiOx) and aluminum oxide (AlOx). The gate insulating layer 210 can protect the semiconductor layer 310 and can separate the semiconductor layer 310 and the gate electrode 320.

The gate electrode 320 can be disposed on the gate insulating layer 210. The gate electrode 320 can be connected to a gate line and a scan signal supplied from the gate driving unit can be applied to the gate electrode 320. For example, the gate electrode 320 can have a single layer or a multiple layer including one of molybdenum (Mo), aluminum (Al), chromium (Cr), gold (Au), titanium (Ti), nickel (Ni), neodymium (Nd), copper (Cu) and an alloy thereof.

A crack detecting part 80 including a material the same as the semiconductor layer 310 and a material the same as the gate electrode 320 can be disposed in the non-display area NA. Although a crack can be formed at various portions, a crack can be generated mainly at a cross-section of the display panel 10 to be spread to an interior. As a result, the crack detecting part 80 can be consecutively disposed along a periphery of the display panel 10. It is not limited thereto, and the crack detecting part 80 can be disposed at various positions. As an example, the crack detecting part 80 can be omitted according to the design.

An interlayer insulating layer 220 can be disposed on the gate electrode 320 of the display area AA. For example, the interlayer insulating layer 220 can include an inorganic material such as silicon nitride (SiNx), silicon oxynitride (SiON), silicon oxide (SiOx), titanium oxide (TiOx) and aluminum oxide (AlOx). The interlayer insulating layer 220 can have a plurality of inorganic layers.

A source electrode 330 and a drain electrode 340 can be disposed on the interlayer insulating layer 220. The source electrode 330 and the drain electrode 340 can be connected to the semiconductor layer 310 through contact holes in the interlayer insulating layer 220 and/or the gate insulating layer 320.

For example, the source electrode 330 and the drain electrode 340 can have a single layer or a multiple layer including one of molybdenum (Mo), aluminum (Al), chromium (Cr), gold (Au), titanium (Ti), nickel (Ni), neodymium (Nd), copper (Cu) and an alloy thereof.

Since functions of the source electrode 330 and the drain electrode 340 are changed according to a material of the semiconductor layer 310, names of the source electrode 330 and the drain electrode 340 can be changed. Since the source electrode 330 or the drain electrode 340 is connected to the data line, the data voltage or a signal can be inputted to the source electrode 330 or the drain electrode 340 to supply a current or a voltage to a first electrode 410 of an emitting element 400.

To planarize step differences due to a thickness difference of various elements, a first planarizing layer 230 and/or a second planarizing layer 250 can be disposed on the TFT 300. As a result, a gap distance between the emitting element 400 and the TFT 300 (or a signal line) increases due to the first planarizing layer 230 and/or the second planarizing layer 250, and an influence of a noise of the TFT 300 (or a signal line) on the emitting element 400 can be reduced.

The first planarizing layer 230 and the second planarizing layer 250 can include an organic material such as polyimide and acrylic resin. The embodiments of the present disclosure are not limited thereto.

An emitting element 400 is disposed on the second planarizing layer 250. The emitting element 400 can include a first electrode 410 (or an anode), a second electrode 420 (or a cathode) corresponding to the first electrode 410 and an emitting layer 430 between the first electrode 410 and the second electrode 420. The first electrode 410 and the emitting layer 430 can be disposed in each subpixel PX, and the second electrode 420 can be disposed in the entire display area AA. As an example, the second electrode 420 can be also individually disposed in each subpixel PX.

The emitting element 400 can be connected to the source electrode 330 or the drain electrode 340 of the TFT 300 through a connecting electrode 420 on the first planarizing layer 230. As an example, the connecting electrode 240 can be omitted, and the emitting element 400 can be directly connected to the source electrode 330 or the drain electrode 340 of the TFT 300.

For example, the connecting electrode 240 can have a single layer or a multiple layer including one of molybdenum (Mo), aluminum (Al), chromium (Cr), gold (Au), titanium (Ti), nickel (Ni), neodymium (Nd), copper (Cu) and an alloy thereof.

The data voltage (current) or a signal can be applied to the first electrode 410 through the TFT 300, and a common voltage EVSS of a low level voltage can be applied to the second electrode 420.

When voltages are applied to the first electrode 410 and the second electrode 420, a hole and an electron are combined with each other in the emitting layer to emit a light.

To apply the common voltage to the second electrode 420, the second electrode 420 can be connected to a first line 450 and a common line 480. The common line 480 can be connected to the data driving unit 50 or the circuit board 30 to supply the common voltage (or the cathode voltage, the ground voltage) to the first line 450, and the first line 450 can be connected to the common line 480 and the second electrode 420 to supply the common voltage to the second electrode 420.

The first line 450 can be individually formed or can be formed by extending the second electrode 420. For example, the first line 450 can include the same metallic material as the first electrode 410 on the second planarizing layer 250. For example, the first line 450 can include the same material as the second electrode 420.

The first line 450 can have a multiple layer including a transparent conductive layer or an opaque conductive layer having a relatively high reflectance. For example, the transparent conductive layer can include indium tin oxide (ITO) or indium zinc oxide (IZO) having a relatively high work function, and the opaque conductive layer can have a single layer or a multiple layer including one of aluminum (Al), silver (Ag), copper (Cu), lead (Pb), molybdenum (Mo), titanium (Ti) and an alloy thereof. The embodiments of the present disclosure are not limited thereto.

The first line 450 can be connected to the second electrode 420 through a contact hole in a bank layer 510 and/or a spacer 520.

The first line 450 can include a plurality of open parts 452. The plurality of open parts 452 can be an outgassing hole for emitting gas therethrough. For instance, the open parts 452 are used to release gas out therethrough. Gas generated in the first planarizing layer 230 or the second planarizing layer 250 of an organic material moves to an upper portion or a side portion thereof. Since the first line 450 covers the first planarizing layer 230 or the second planarizing layer 250 of a gas moving path, without the open parts 452, gas may be prevented from being emitted out to an exterior. As a result, to emit gas generated in an organic layer in the present disclosure, the plurality of open parts 452 are provided in the first line 450 and are used to emit (e.g., pass or release) gas therethrough.

Further, if the plurality of open parts 452 were disposed in the display area AA, gas can deteriorate an organic layer of the emitting element 400 in the display area AA. Accordingly, the plurality of open parts 452 are disposed in the non-display area NA in the present disclosure. Another part of the first line 450 except for the plurality of open parts 452 can include a conductive layer where a voltage or a current is transmitted. Another part of the first line 450 can be a mesh part having a net shape or a continuous part having a plate shape. As an example, at least a part of the plurality of open parts 452 can be disposed in the display area AA.

A common line 480 connected to the first line 450 to apply a common voltage to the first line 450 can be disposed in a region corresponding to an end portion of the first line 450. The common line 480 can include a first common line 482 including the same metallic material as the source electrode 330 and a second common line 484 including the same metallic material as the connecting electrode 240. For example, the common line 480 can be formed by laminating the first common line 482 and the second common line 484. As an example, the common line 480 can include a single layer or a multiple layer, and/or can include a different material from the source electrode 330 or the connecting electrode 240.

The first line 450 and the common line 480 can be connected to each other through a contact hole in the first planarizing layer 230 and/or the second planarizing layer 250.

When a gate driving unit 70 in the non-display area NA of the substrate 110 has a gate-in-panel (GIP) type, a gate driving circuit having a plurality of TFTs can be disposed in the non-display area NA.

The plurality of TFTs of the gate driving circuit can have the same layers as the TFT 300 driving the emitting element 400. For example, electrodes of the plurality of TFTs of the gate driving circuit can include the same metallic material as the source electrode 330 of the TFT 300 driving the emitting element 400 or the same metallic material as the connecting electrode 240 connecting the emitting element 400 and the TFT 300.

To reduce the non-display area NA, the gate driving unit 70 can be disposed under the first line 450.

The first electrode 410 in the display area AA can have a multiple layer including a transparent conductive layer or an opaque conductive layer having a relatively high reflectance. The transparent conductive layer can include a material having a relatively high work function such as indium tin oxide (ITO) and indium zinc oxide (IZO), and the opaque conductive layer can have a single layer or a multiple layer of aluminum (Al), silver (Ag), copper (Cu), lead (Pb), molybdenum (Mo), titanium (Ti) and an alloy thereof. The embodiments of the present disclosure are not limited thereto.

For example, the first electrode 410 can have a structure where a transparent conductive layer, an opaque conductive layer and a transparent conductive layer are sequentially disposed or a structure where a transparent conductive layer and an opaque conductive layer are sequentially disposed. The embodiments of the present disclosure are not limited thereto.

The emitting layer 430 can have a hole relating layer, an emitting material layer and an electron relating layer sequentially or reversely sequentially disposed on the first electrode 410. As an example, at least one of the hole relating layer and the electron relating layer can be omitted.

A bank layer 510 can be disposed between the emitting layers 430. The bank layer 510 can be disposed on the first electrode 410 in each subpixel PX and can be referred to as a pixel defining layer exposing the first electrode 410. For example, the bank layer 510 can be disposed on the first electrode 410 in the non-display area NA to cover a portion of the first electrode 410.

The bank layer 510 can include a transparent material or an opaque material for preventing an optical interference between the adjacent subpixels PX. For example, the bank layer 510 can include a light shielding material such as one of a color pigment, an organic black and a carbon.

A spacer 520 can be disposed on the bank layer 510. A fine metal mask (FMM) of an evaporation mask for forming the emitting layer 430 of the emitting element 440 can be supported by the bank layer 510 in the non-display area NA on the substrate 110. To prevent a damage due to contact of the bank layer 510 and the evaporation mask and keep a constant distance between the bank layer 510 and the evaporation mask, the spacer 520 including a transparent organic material such as one of polyimide (PI), photoacryl (PAC) and benzocyclobutene (BCB) can be disposed on the bank layer 510.

A dam can be disposed in the non-display area NA on the substrate 110. The dam can be disposed to prevent an encapsulating part on the second electrode 420 from flowing toward an outer portion of the display panel 10.

The dam can include a plurality of first dams 550 and a second dam 560 at a periphery of the plurality of first dams 550.

Each of the plurality of first dams 550 and the second dam 560 can include at least one of a first lower dam layer 554 having the same material as the bank layer 510 and a first upper dam layer 552 having the same material as the spacer 520. For example, the first dam 550 can have a laminated structure of the lower dam layer 554 and the upper dam layer 552 by forming and patterning the spacer 520. For example, the first lower dam layer 554 can have the same material as the bank layer 510 and/or the first upper dam layer 552 can have the same material as the spacer 520.

The plurality of first dams 550 can be disposed on the first line 450. For example, the plurality of first dams 550 can be disposed on the plurality of open parts 452 of the first line 450. Each of the plurality of first dams 550 can be disposed to correspond to and overlap each of the plurality of open parts 452. Further, each of the plurality of first dams 550 can be disposed to partially overlap the conductive layer of the first line 450. As a result, the plurality of open parts 452 of the first line 450 can be covered with the first dam 550, and a portion of the conductive layer of the first line 450 can be exposed outside the first dam 550. As an example, each of the plurality of first dams 550 can be disposed to correspond to and overlap at least one of the plurality of open parts 452. As an example, at least one of the plurality of open parts 452 cannot be covered with the first dam 550. As an example, at least a part of each of the plurality of open parts 452 cannot be covered with the first dam 550.

The exposed conductive layer of the first line 450 can contact the second electrode 420. The second electrode 420 can be disposed on the plurality of first dams 550 and can contact the exposed conductive layer of the first line 450.

For example, the second electrode 420 can be disposed along a contact hole in the bank layer 510 and/or the spacer 520 to be connected to the first line 450. Since the first dam 550 is formed due to the contact hole in the bank layer 510 and/or the spacer 520 and the second electrode 420 is connected to the first line 450 exposed between the first dams 550, a contact resistance can be reduced.

The second electrode 420 can be disposed along a portion of a top surface of the plurality of first dams 550 and can contact the conductive layer of the first line 450 between the first dams 550 in a plurality of regions.

Since the plurality of first dams 550 are disposed to cover an edge portion of the conductive layer of the first line 450, generation of a residual material of the first line 450 can be prevented in a patterning process after forming the first line 450. As a result, deterioration of driving due to injection of the residual material of the first line 450 into the display area AA can be prevented.

A second electrode 420 can be disposed on the bank layer 510, the spacer 520, the plurality of first dams 550 and the emitting layer 430. The second electrode 420 can face into the first electrode 410 with the emitting layer 430 interposed therebetween and can be disposed on a top surface and a side surface of the emitting layer 430.

The second electrode 420 can be disposed on the entire display area AA as one body. In a top emission type organic light emitting diode (OLED) display device, the second electrode can include a transparent conductive material such as indium tin oxide (ITO) and indium zinc oxide (IZO).

An encapsulating part 600 for reducing or preventing penetration of a moisture and an external particle can be disposed on the second electrode 420 of the emitting element 400. The encapsulating part 600 can include a first encapsulating layer 610, a second encapsulating layer 620 and a third encapsulating layer 630 sequentially disposed on the second electrode 420. The embodiments of the present disclosure are not limited thereto.

The first encapsulating layer 610 and the third encapsulating layer 630 of the encapsulating part 600 can include an inorganic material such as silicon oxide (SiOx). The second encapsulating layer 620 of the encapsulating part 600 can include an organic material such as acrylic resin, epoxy resin, phenolic resin, polyamide resin and polyimide resin. The embodiments of the present disclosure are not limited thereto.

The second dam 560 having the same material as the bank layer 510 and the spacer 520 can be disposed at an end portion of the second encapsulating layer 620. The first encapsulating layer 610 and the third encapsulating layer 630 can be disposed on the second dam 560. As an example, the second encapsulating layer 620 cannot be disposed on the second dam 560.

The second dam 560 can prevent the second encapsulating layer 620 from flowing toward an outer portion of the display panel 10 during a process of forming the encapsulating part 600. Since the second encapsulating layer 620 of an organic material has a relatively great thickness and a fluidity to planarize a step difference under the second encapsulating layer 620, a dam is required for blocking a flow of the second encapsulating layer 620.

Since the second dam 560 is formed by extending a portion of the encapsulating part 600, the second dam 560 can have a sealing function to protect the subpixel PX from a moisture injected into the display panel 10.

To prevent a flow of the second encapsulating layer 620 toward a periphery, the dam can be formed to have a plural number. As the number of the dam increases, the non-display area NA can be enlarged and a size of the display panel 10 can increase.

To prevent an increase of the non-display area NA, then the first dam 550 can be disposed between the second dam 560 and the display area AA. Increase of the non-display area NA can be prevented or minimized by disposing the first dam 550 adjacent to the display area AA.

To dispose the first dam 550 between the second dam 560 and the display area AA, the first dam 550 can be disposed on the first line 450. Further, the first dam 550 can be disposed in a region where the gate driving unit 70 is disposed.

Since the first dam 550 is disposed on the first planarizing layer 230 and the second planarizing layer 250, a height of the first dam 550 can be smaller than a height of the second dam 560. As a result, a flow of the second encapsulating layer 620 can be effectively is blocked with the first dam 560 having a relatively small height by forming the first dam 550 to have a plural number.

The plurality of first dams 550 can reduce a flow of the second encapsulating layer 620 rather than the plurality of first dams 550 can block the second encapsulating layer 620. When the plurality of first dams 550 reduces a flow of the second encapsulating layer 620, the second dam 560 at an outermost region can effectively block a flow of the second encapsulating layer 620.

As a result, the first encapsulating layer 610, the second encapsulating layer 620 and the third encapsulating layer 630 can be disposed on the plurality of first dams 550, and the first encapsulating layer 610 and the third encapsulating layer 630 can be disposed on the second dam 560. As an example, the second encapsulating layer 620 cannot be disposed on the second dam 560.

A touch sensor can be disposed on the encapsulating part 600. The touch sensor can include a lower electrode, an upper electrode and a touch insulating layer between the lower electrode and the upper electrode.

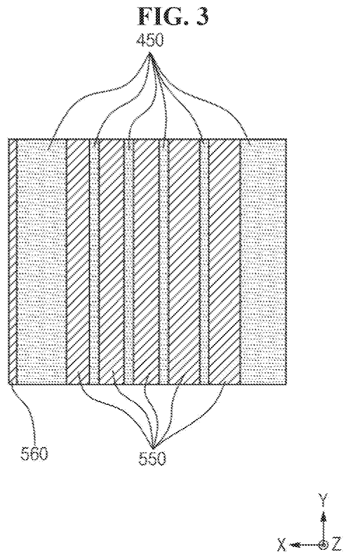

FIG. 3 is a plan view corresponding to line B-B′ of FIG. 2.

In FIG. 3, the plurality of first dams 550 can be disposed along a first direction (e.g., a Y axis) or a second direction (e.g., an X axis) to have a stripe shape. Since the plurality of first dams 550 and the second dam 560 are disposed along a periphery of the display panel 10, the plurality of first dams 550 can be disposed along the first direction in left and right regions of the display panel 10 in a plan view and along the second direction in upper and lower regions of the display panel 10 in a plan view.

The second dam 560 can be disposed along the first direction in left and right regions of the display panel 10 in a plan view and along the second direction in upper and lower regions of the display panel 10 in a plan view.

The plurality of first dams 550 and the second dam 560 can be consecutively disposed along a boundary of the display panel 10 or can be separately disposed along a boundary of the display panel 10 to have cut regions. The disposition structure of the plurality of first dams 550 and the second dam 560 is not limited thereto and can vary according to a product structure.

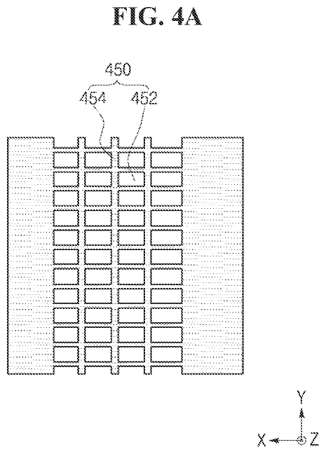

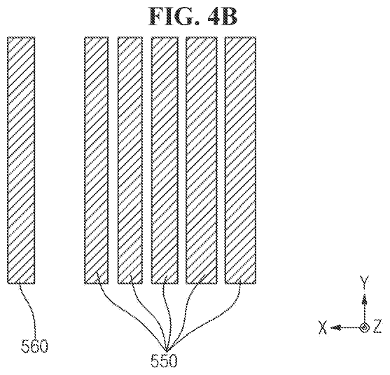

FIG. 4A is a plan view showing a first line of a display device according to an embodiment of the present disclosure, and FIG. 4B is a plan view showing a first dam of a display device according to an embodiment of the present disclosure.

FIGS. 4A and 4B show the first line 450 and the first dam 550, respectively, separated from each other.

In FIG. 4A, the first line 450 can have the plurality of open parts 452 for emitting gas generated in an organic layer under the first line 450.

The plurality of open parts 452 can have various shapes. When the plurality of open parts 452 are separated from each other to have a tetragonal shape, the conductive layer of the first line 450 except for the plurality of open parts 452 can be a mesh part 454 having a net shape.

As a result, the first line 450 can include the plurality of open parts 452 and the meth part 454.

The shape of the plurality of open parts 452 is not limited thereto, and each of the plurality of open parts 452 can have various shapes such as a circular shape and a polygonal shape for effectively emitting gas generated in an organic layer. The position of the plurality of open parts 452 is not limited thereto, and the position of the plurality of open parts 452 can vary according to a gas emission and a position of the plurality of first dams 550. As an example, the shape and/or size of the plurality of open parts 452 can vary according to a position.

The shape of the mesh part 454 can vary according to a position and a shape of the plurality of open parts 452. For example, the shape of the mesh part 454 can vary for effectively supply the common voltage applied to the first line 450.

Since the first line 450 is connected to the common line 480 to supply the common voltage to the second electrode 420, the first line 450 is entirely connected to form the mesh part 454 of a net shape.

In FIG. 4B, the plurality of first dams 550 can have a stripe shape. The plurality of first dams 550 can be disposed to overlap the plurality of open parts 452 of the first line 450 and to overlap a portion of the mesh part 454 of the first line 450.

When the plurality of first dams 550 are disposed to overlap the entire open parts 452 of the first line 450 and a portion of the mesh part 454, the plurality of first dams 550 can be fixed by the plurality of open parts 452 and the mesh part 454 having a step difference, and the plurality of first dams 550 of an organic material can contact the second planarizing layer 250 of an organic material through the plurality of open parts 452. As a result, an adhesion can be improved.

Since the plurality of first dams 550 can have a stripe shape and entirely overlap a portion of the mesh part 454 along the first direction (the Y axis), a fixation force can be further improved.

Since the plurality of first dams 550 are disposed to cover an end portion of the mesh part 454 along the first direction (the Y axis), the residual material of the first line 450 generated during a patterning process of the bank layer 510 or the spacer 520 after forming the first line 450 can be prevented. As a result, deterioration of driving due to the injection of the residual material of the first line 450 into the display area AA can be prevented.

Consequently, in the display device according to an embodiment of the present disclosure, since the non-display area is reduced by disposing the plurality of dams on the first line where the driving voltage (or the common voltage, the driving signal) is applied, a portability and a design are improved.

Further, since an area where the first line and the first electrode are connected is enlarged by contacting the first line exposed between the plurality of dams and the first electrode of the emitting element, a contact resistance of the first line and the first electrode is reduced and a display quality is improved.

Example embodiments of the present disclosure can also be described as follows:

According to an example embodiment of a present disclosure, a display device includes a substrate having a display area displaying an image and a non-display area surrounding the display area; a thin film transistor disposed on the substrate and including a semiconductor layer, a gate electrode, a source electrode and a drain electrode; an emitting element disposed on the thin film transistor in the display area and including a first electrode, an emitting layer and a second electrode; an encapsulating part on the emitting element; a first line in the non-display area, the first line including a same metallic material as the first electrode and connected to the second electrode; and a plurality of first dams on the first line, wherein the first line includes a plurality of open parts, and the plurality of first dams are disposed on the plurality of open parts.

In some example embodiments, the display device further includes bank layer disposed on the thin film transistor and covering a portion of the first electrode; and a spacer on the bank layer, wherein each of the plurality of first dams includes at least one of a lower dam layer having a same material as the bank layer and an upper dam layer having a same material as the spacer.

In some example embodiments, the first line includes a mesh part in a region except for the plurality of open parts, and the plurality of first dams are disposed along one of a first direction and a second direction to have a stripe shape.

In some example embodiments, the plurality of first dams are disposed to overlap the plurality of open parts.

In some example embodiments, the plurality of first dams are disposed to overlap a portion of the mesh part.

In some example embodiments, the second electrode is disposed on the plurality of first dams and contacts the first line between the plurality of first dams.

In some example embodiments, each of the plurality of open parts is an outgassing hole emitting gas.

In some example embodiments, the display device further includes a second dam disposed outside the plurality of first dams.

In some example embodiments, the encapsulating part includes a first encapsulating layer, a second encapsulating layer and a third encapsulating layer, the first encapsulating layer, the second encapsulating layer and the third encapsulating layer are disposed on the plurality of first dams, and the first encapsulating layer and the third encapsulating layer are disposed on the second dam.

In some example embodiments, the display device further includes a common line connected to the first line and applying a common voltage to the first line, and the common line includes a first common line having a same material as the source electrode.

In some example embodiments, the display device further includes a connecting electrode connecting the thin film transistor and the emitting element, and the common line further includes a second common line having a same material as the connecting electrode.

In some example embodiments, the display device further includes a gate driving unit in the non-display area.

In some example embodiments, the gate driving unit has a gate-in-panel type.

In some example embodiments, the display device further includes a planarizing layer covering the gate driving unit.

In some example embodiments, the plurality of first dams are disposed on the planarizing layer, and a portion of the plurality of first dams overlaps the gate driving unit.

It will be apparent to those skilled in the art that various modifications and variation can be made in the present disclosure without departing from the scope of the disclosure. Thus, it is intended that the present disclosure cover the modifications and variations of this disclosure, provided they come within the scope of the appended claims and their equivalents.

What is claimed is:

1. A display device, comprising:
a substrate having a display area configured to display an image and a non-display area adjacent to the display area;
a thin film transistor disposed on the substrate and including a semiconductor layer, a gate electrode, a source electrode and a drain electrode;
an emitting element disposed on the thin film transistor in the display area and including a first electrode, an emitting layer and a second electrode;
an encapsulating part disposed on the emitting element;
a first line disposed in the non-display area, the first line including a same metallic material as the first electrode and connected to the second electrode; and
a plurality of first dams disposed on the first line,
wherein the first line includes a plurality of open parts, and the plurality of first dams are disposed on the plurality of open parts.

2. The display device of claim 1, further comprising:
a bank layer disposed on the thin film transistor and covering a portion of the first electrode; and
a spacer disposed on the bank layer,
wherein each of the plurality of first dams includes at least one of a lower dam layer having a same material as the bank layer and an upper dam layer having a same material as the spacer.

3. The display device of claim 1, wherein the first line includes a mesh part disposed in a region except for the plurality of open parts, and
wherein the plurality of first dams are disposed along one of a first direction and a second direction to have a stripe shape.

4. The display device of claim 3, wherein the plurality of first dams are disposed to overlap the plurality of open parts.

5. The display device of claim 3, wherein the plurality of first dams are disposed to overlap a portion of the mesh part.

6. The display device of claim 3, wherein the second electrode is disposed on the plurality of first dams and contacts the first line between the plurality of first dams.

7. The display device of claim 1, wherein each of the plurality of open parts is an outgassing hole for emitting gas.

8. The display device of claim 1, further comprising a second dam disposed outside the plurality of first dams.

9. The display device of claim 8, wherein a height of the first dam is smaller than a height of the second dam.

10. The display device of claim 8, wherein the encapsulating part includes a first encapsulating layer, a second encapsulating layer and a third encapsulating layer,
wherein the first encapsulating layer, the second encapsulating layer and the third encapsulating layer are disposed on the plurality of first dams, and the first encapsulating layer and the third encapsulating layer are disposed on the second dam.

11. The display device of claim 8, wherein the second dam is disposed at an end portion of the second encapsulating layer.

12. The display device of claim 1, further comprising a common line connected to the first line and applying a common voltage to the first line,
wherein the common line includes a first common line having a same material as the source electrode.

13. The display device of claim 12, further comprising a connecting electrode connecting the thin film transistor and the emitting element,
wherein the common line further includes a second common line having a same material as the connecting electrode.

14. The display device of claim 1, further comprising a gate driving unit disposed in the non-display area.

15. The display device of claim 14, wherein the gate driving unit is a gate-in-panel type.

16. The display device of claim 14, further comprising a planarizing layer covering the gate driving unit.

17. The display device of claim 16, wherein the plurality of first dams are disposed on the planarizing layer, and a portion of the plurality of first dams overlaps the gate driving unit.

18. The display device of claim 1, wherein the first line includes a mesh pattern, and at least one of the plurality of first dams overlaps a portion of the mesh pattern.
